(19) United States
(12) Patent Application Publication
(10) Pub. No.: US 2026/0255842 A1
(43) Pub. Date: Aug. 27, 2026

(54) DISPLAY PANEL AND ELECTRONIC DEVICE INCLUDING THE SAME

(71) Applicant: Samsung Display Co., Ltd., Yongin-si (KR)

(72) Inventors: Arong LEE, Yongin-si (KR); Kyongsub KIM, Yongin-si (KR)

(73) Assignee: Samsung Display Co., Ltd., Yongin-si (KR)

(21) Appl. No.: 19/422,756

(22) Filed: Dec. 17, 2025

(30) Foreign Application Priority Data
Feb. 27, 2025 (KR) 10-2025-0025941
Apr. 14, 2025 (KR) 10-2025-0048342

(51) Int. Cl. H10K 59/80; H10K 59/122

(52) U.S. Cl. CPC H10K 59/80515; H10K 59/122

(57) ABSTRACT

Some example embodiments of the inventive concepts provide a display panel including a base layer including a plurality of emission areas and a non-emission area which surrounds the plurality of emission areas, a circuit layer on the base layer, and a display layer on the circuit layer and including a plurality of light emitting elements corresponding to the plurality of emission areas. Each of the plurality of light emitting elements includes a first electrode, a second electrode on the first electrode, a functional layer between the first electrode and the second electrode and having a top surface that at least partially defines a first groove that at least partially overlaps the non-emission area, and a pattern layer in the first groove. The pattern layer includes an acid material.

### CROSS-REFERENCE TO RELATED APPLICATIONS

This U.S. non-provisional patent application claims priority under 35 U.S.C. § 119 to Korean Patent Application Nos. 10-2025-0025941, filed on Feb. 27, 2025, and 10-2025-0048342, filed on Apr. 14, 2025, the entire contents of which are hereby incorporated by reference.

### BACKGROUND

Some example embodiments of the present disclosure relate to a display panel with improved efficiency and lifespan and an electronic device including the display panel.

Multimedia electronic devices such as televisions, mobile phones, tablet computers, navigation units, game consoles, or wearable devices may include display panels which display images. A display panel may include a self-emissive light emitting element in an emission layer disposed between electrodes facing each other. The self-emissive light emitting element may include a light emitting material such as an organic compound, a quantum dot, or the like. The light emitting material emits light to provide a display.

Improvement in luminance efficiency and lifespan of the light emitting element is desirable to improve display quality of the display panel and of an electronic device that may include the display panel.

### SUMMARY

Some example embodiments of the present disclosure provide a display panel having improved luminance efficiency and improved lifespan characteristics, and an electronic device including the display panel.

Some example embodiments of the present disclosure also provide a method for manufacturing a display panel including a light emitting element with improved efficiency and lifespan.

Some example embodiments of the inventive concepts provides a display panel including a base layer including a plurality of emission areas and a non-emission area that surrounds the plurality of emission areas, a circuit layer on the base layer, and a display layer on the circuit layer and including a plurality of light emitting elements corresponding to the plurality of emission areas. Each of the plurality of light emitting elements includes a first electrode, a second electrode on the first electrode, a functional layer between the first electrode and the second electrode and having a top surface at least partially defining a first groove that at least partially overlaps the non-emission area, and a pattern layer in the first groove. The pattern layer may include an acid material.

In some example embodiments, a material included in each of the plurality of light emitting elements may be different from a material included in the pattern layer.

In some example embodiments, the acid material may include a polyacrylic acid or a citric acid.

In some example embodiments, the functional layer may include a first emission part on the first electrode and a second emission part on the first emission part, and the second emission part may at least partially define the first groove.

In some example embodiments, the first emission part may include a hole transport layer and an emission layer on the hole transport layer, the second emission part may include an electron transport layer on the emission layer. The pattern layer is configured such that hydrogen ions from the acid material are provided to the electron transport layer.

In some example embodiments, the first emission part may include a hole transport layer, the second emission part may include an emission layer on the hole transport layer and an electron transport layer on the emission layer. The pattern layer is configured such that hydrogen ions from the acid material are provided to the electron transport layer.

In some example embodiments, the display layer may further include a pixel defining film that exposes at least a portion of a top surface of the first electrode through a pixel opening portion defined in the pixel defining film. The first emission part may be in the pixel opening portion, and the second emission part may include a first portion in the pixel opening portion, and a second portion on the pixel defining film and the second portion having a top surface that may define the first groove.

In some example embodiments, the pixel defining film may include a first layer on the circuit layer and a second layer on a top surface of the first layer. The top surface of the first layer defines a second groove, the second groove corresponding to the first groove.

In some example embodiments, the second layer may be spaced apart from the first groove and the second groove on a plane.

In some example embodiments, the second layer may have a shape extending in a first direction.

In some example embodiments, the second layer includes a material having a higher liquid-repellency than a material included in the first layer.

In some example embodiments, the circuit layer may include a plurality of insulating layers and an organic layer on the plurality of insulating layers. A top surface of the organic layer defines a third groove corresponding to the second groove.

In some example embodiments, the plurality of emission areas may include a plurality of first emission areas, each of which are configured to emit a first light and are aligned in a first direction, and a plurality of second emission areas, each of which are configured to emit a second light and are aligned in the first direction.

In some example embodiments, the first light may be a red light or a green light, and the second light may be a blue light.

In some example embodiments, the non-emission area may include a first non-emission area between the plurality of first emission areas, and a second non-emission area between the plurality of second emission areas.

In some example embodiments, the first groove may include a plurality of (1-1)-th grooves at least partially overlapping the first non-emission area, and a plurality of (1-2)-th grooves at least partially overlapping the second non-emission area. The plurality of (1-1)-th grooves and the plurality of first emission areas may be alternated in the first direction, and the plurality of (1-2)-th grooves and the plurality of second emission areas may be alternated in the first direction.

In some example embodiments, the pattern layer may include a first pattern layer in the plurality of (1-1)-th grooves and a second pattern layer in the plurality of (1-2)-th grooves, and a thickness of the first pattern layer may be different from a thickness of the second pattern layer.

In some example embodiments of the inventive concepts, a display panel includes a base layer including a plurality of first emission areas, each of which are configured to emit a first light, a plurality of second emission areas, each of which are configured to emit a second light different from the first light, a first non-emission area between the plurality of first emission areas, and a second non-emission area between the plurality of second emission areas, a circuit layer on the base layer, and a display layer on the circuit layer and including a plurality of first light emitting elements corresponding to the plurality of first emission areas and a plurality of second light emitting elements corresponding to the plurality of second emission areas. Each of the plurality of first light emitting elements includes a first anode, a first cathode on the first anode, and a first functional layer between the first anode and the first cathode. Each of the plurality of second light emitting elements includes a second anode, a second cathode on the second anode, and a second functional layer between the second anode and the second cathode. A top surface of the first functional layer defines a first recess pattern that at least partially overlaps the first non-emission area, and a top surface of the second functional layer defines a second recess pattern that at least partially overlaps the second non-emission area and has a different thickness than the first recess pattern.

In some example embodiments of the inventive concepts, an electronic device includes a display device which provides an image and includes a display panel, and a power module which supplies power to the display device. The display panel includes a base layer including a plurality of emission areas and a non-emission area surrounding the plurality of emission areas, a circuit layer on the base layer, and a display layer on the circuit layer and including a plurality of light emitting elements corresponding to the plurality of emission areas. Each of the plurality of light emitting elements includes a first electrode, a second electrode on the first electrode, a functional layer between the first electrode and the second electrode and having a top surface that defines a first groove that may at least partially overlap the non-emission area, and a pattern layer in the first groove. The pattern layer may include an acid material.

In some example embodiments, the electronic device may further include a processor and a memory.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a block diagram of an electronic device according to some example embodiments.

FIG. 2 is a schematic view of electronic devices according to some example embodiments.

FIG. 3 is a perspective view of an electronic device according to some example embodiments.

FIG. 4 is a perspective view of a display device according to some example embodiments.

FIG. 5 is a plan view of a display device according to some example embodiments.

FIG. 6 is a cross-sectional view of a display device according to some example embodiments.

FIG. 7 is a cross-sectional view of a portion of a display panel according to some example embodiments.

FIG. 8 is a cross-sectional view of a light emitting element according to some example embodiments.

FIG. 9 is a plan view of a display panel according to some example embodiments.

FIGS. 10A and 10B are each a cross-sectional view of a portion of a display panel according to some example embodiments.

FIGS. 11A, 11B, 11C, 11D, 11E, and 11F illustrate example operations in a method for manufacturing a display panel according to some example embodiments.

FIGS. 12A, 12B, 12C, 12D, 12E, and 12E illustrate example operations in a method for manufacturing a display panel according to some example embodiments.

### DETAILED DESCRIPTION

Example embodiments of the inventive concepts may be modified in various forms, and embodiments thereof will be illustrated in the drawings and described herein in detail. Example embodiments of the inventive concepts should not be construed as limited to the embodiments set forth herein. Rather, these embodiments are provided so that this disclosure will be thorough and complete, and will fully convey the scope of the inventive concepts to those skilled in the art.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concepts. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, “being directly disposed” may mean that there is no additional layer, film, region, plate or the like between a part such as a layer, film, region, plate or the like and another part. For example, “being directly disposed” may mean that two layers or two members are disposed with no additional member such as an adhesive member.

As used herein, “an area/portion corresponding to another area/portion” means that the areas/portions “overlap each other”, and is not limited to the meaning that the areas/portions have the same surface area and/or the same shape. In addition, as used herein, “an area/portion overlapping another area/portion” means that the areas/portions overlap each other when viewed on a plane, and includes a case in which the area/portion at least partially overlap the other area/portion on a plane.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, a display panel according to some example embodiments and an electronic device according to some example embodiments are described with reference to the accompanying drawings.

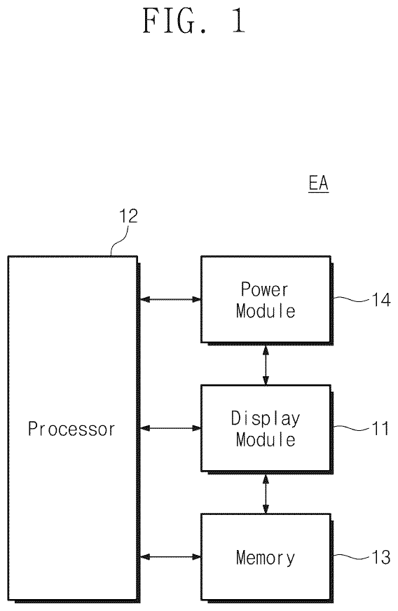

FIG. 1 is a block diagram of an electronic device according to some example embodiments. Referring to FIG. 1, an electronic device EA, according to some example embodiments, may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data used for an operation of the processor 12 or the display module 11. When the processor 12 executes an application stored in the memory 15, an image data signal and/or an input control signal may be transmitted to the display module 11, and the display module 11 may process the received signal and output image information through a display screen. The display module 11 may include a display panel which displays an image.

The power module 14 may include a power supply module such as a power adapter or a battery device, and a power conversion module which converts the power supplied by the power supply module and generates power necessary for an operation of the electronic device EA.

At least one of the components of the electronic device EA described above may be included in a display device including the display panel according to some example embodiments. In addition, some individual modules included as functional in one module may be included in the display device, and others may be provided separately from the display device. For example, the display device may include the display module 11, and the processor 12, the memory 13, and the power module 14 may be provided not in the display device but in another type of device in the electronic device EA.

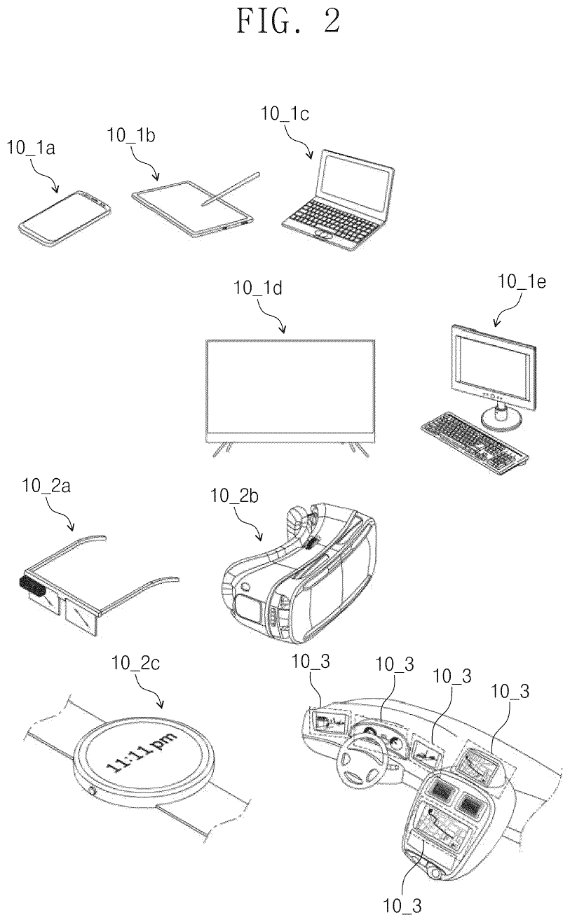

FIG. 2 is a schematic view of electronic devices according to some example embodiments.

Referring to FIG. 2, different electronic devices including a display device according to some example embodiments may include an electronic device for a displaying image, e.g., a smartphone 10_1a, a tablet PC 10_1b, a laptop computer 10_1c, TV 10_1d, and a monitor for a desk computer 10_1e, a wearable electronic device including a display module, e.g., smart glasses 10_2a, a head mounted display 10_2b, and a smartwatch 10_2c, and a vehicle electronic device 10_3 including a display module, e.g., a vehicle instrument panel, a center fascia, a center information display (CID) disposed on a dashboard, and a room mirror display.

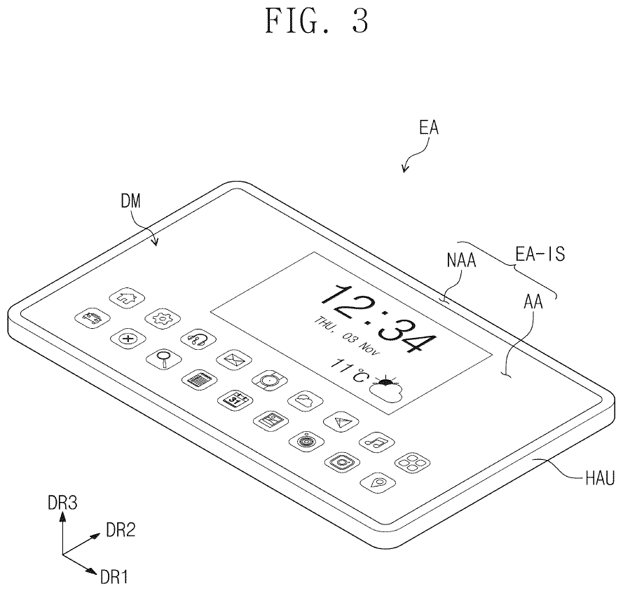

FIG. 3 is a perspective view illustrating an electronic device according to some example embodiments.

An electronic device EA according to some example embodiments may include a display device DM which displays an image through a display surface EA-IS. The display device DM may be accommodated and/or disposed in a housing HAU. The electronic device EA may include the display device DM and a controller which controls an operation of the display device DM.

The display surface EA-IS of the electronic device EA may have a rectangular shape having longer sides extending in a first direction DR1 and shorter sides extending in a second direction DR2 crossing the first direction DR1 on a plane. However, some example embodiments of the inventive concepts are not limited thereto, and the display surface EA-IS may have various other shapes such as a circular shape or a polygonal shape.

As used herein, a third direction DR3 may be defined as a direction substantially perpendicular to a plane defined by the first direction DR1 and the second direction DR2. A front surface (or top surface) and a rear surface (or bottom surface) of each of members, which constitute the electronic device EA, may be opposite each other in the third direction DR3, and a normal direction to each of the front surface and the rear surface may be substantially parallel to the third direction DR3. A separation distance between the front surface and the rear surface, which is defined in the third direction DR3, may correspond to a thickness of the member.

The term “on a plane” used herein may be defined as being in a state when viewed in the third direction DR3. For example, the term “on a plane” may be described on the basis of a plane defined by the first direction DR1 and the second direction DR2 together. The term “on a cross-section” used herein may be defined as being in a state when viewed in the first direction DR1 or the second direction DR2. Directions indicated by the first to third directions DR1, DR2 and DR3 are relative concepts and may be changed to other directions.

FIG. 3 illustrates a tablet terminal as an example of the electronic device EA. Electronic modules, a camera module, a power module and the like, mounted on a main board, may be disposed in a bracket/housing HAU or the like together with the display device DM, thereby constituting the tablet terminal. However, example embodiments are not limited thereto, and the display device DM and the display panel according to some example embodiments may be used in a relatively large-sized electronic device such as television, monitor, and outdoor billboard, and in relatively smaller and medium-sized electronic device such as personal computer, notebook computer, personal digital assistant, vehicle navigation unit, game console, smartphone, tablet computer, smartwatch, and camera. However, these are mere example, and the display device DM according to some example embodiments may be also used in other electronic devices, without departing from the scope of the disclosure. The electronic device EA including the display device DM may be also referred to as a display device.

Some example embodiments illustrate the electronic device EA including the display device DM having a flat display surface, but example embodiments of the inventive concepts are not limited thereto. The electronic device EA may include a curved display surface or a three-dimensional display surface. For example, the three-dimensional display surface may include a plurality of display areas oriented in different directions and include a bent display surface. The electronic device EA according to some example embodiments may be a flexible electronic device. The flexible electronic device may be a foldable electronic device configured to be folded.

As illustrated in FIG. 3, the display surface EA-IS includes an active area AA on which an image is displayed, and a bezel area NAA adjacent to or along the outer periphery of the active area AA. The bezel area NAA is an area on which an image is not displayed. FIG. 3 illustrates icon images as one example of the image. The active area AA may be referred to as a display area of the display device DM, and the bezel area NAA may be referred to as a non-display area of the display device DM.

As illustrated in FIG. 3, the active area AA may have a substantially rectangular shape. The “substantially rectangular shape” includes not only a rectangular shape in terms of mathematics, but also a rectangular shape in which not a vertex but a curved boundary is defined on a vertex area (or corner area).

The bezel area NAA may surround the active area AA. However, the shape of the bezel area NAA is not limited thereto and may be changed. For example, the bezel area NAA may be disposed on only one side of the active area AA.

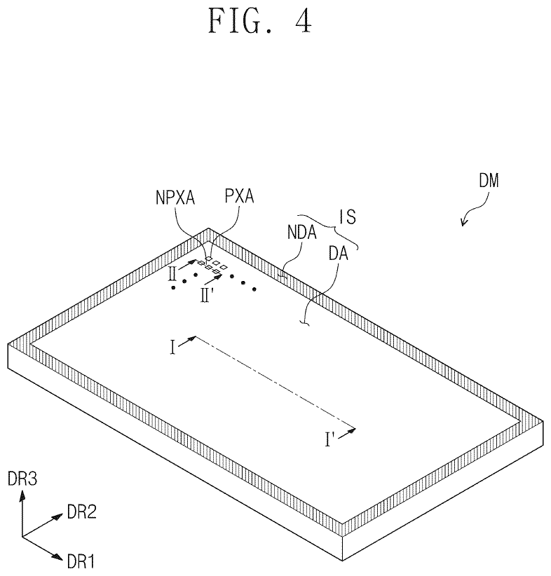

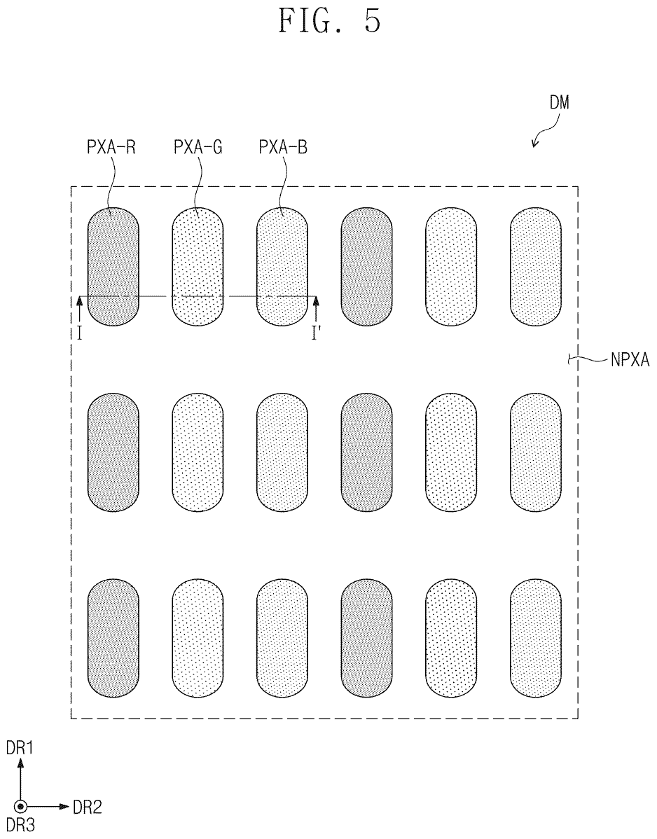

FIG. 4 is a perspective view of a display device according to some example embodiments of the inventive concepts. FIG. 5 is a plan view of a display device according to some example embodiments of the inventive concepts. FIG. 5 illustrates an enlarged portion of a display area DA of a display device DM illustrated in FIG. 4.

Referring to FIG. 4, the display device DM may include a display surface IS, and the display device DM may display an image through or using the display surface IS. The display surface IS of the display device DM may correspond to a display surface EA-IS of an electronic device EA (FIG. 3).

The display surface IS may include the display area DA and a non-display area NDA. A plurality of emission areas PXA may be disposed in the display area DA. A non-emission area NPXA is disposed around (and separating) the emission areas PXA.

The emission areas may not be disposed in the non-display area NDA of the display surface IS, and the non-display area NDA may surround the display area DA. However, some example embodiments of the inventive concepts are not limited thereto, and in some example embodiments of the inventive concepts, the non-display area NDA may be omitted or be disposed on only one side of the display area DA.

Referring to FIGS. 4 and 5, the display area DA may include a plurality of emission areas PXA-R, PXA-G and PXA-B and the non-emission area NPXA which surrounds the plurality of emission areas PXA-R, PXA-G and PXA-B. The plurality of emission areas PXA-R, PXA-G and PXA-B may be arranged in a stripe shape on a plane. The plurality of emission areas PXA-R, PXA-G and PXA-B may be arranged in the first direction DR1 or the second direction DR2. However, some example embodiments are not limited thereto, and the arrangement (or configuration) of the emission areas PXA-R, PXA-G and PXA-B may include a PenTile (PENTILE™) arrangement, or a diamond (Diamond Pixel™) arrangement.

The emission areas PXA-R, PXA-G and PXA-B may each correspond to an area from which light provided from a light emitting element is emitted. The emission areas PXA-R, PXA-G and PXA-B may include a first emission area PXA-R, a second emission area PXA-G, and a third emission area PXA-B. The first to third emission areas PXA-R, PXA-G and PXA-B may be divided according to colors of light emitted to the outside from the electronic device EA. The non-emission area NPXA may set a boundary between the first to third emission areas PXA-R, PXA-G and PXA-B, and prevent or limit or reduce color mixture between the first to third emission areas PXA-R, PXA-G and PXA-B.

Among the first to third emission areas PXA-R, PXA-G and PXA-B, a first one may provide light of a first color corresponding to source light provided by a light emitting element, a second one may provide light of a second color different from the light of the first color, and the third one may provide light of a third color different from the light of the first color and the light of the second color. For example, the light of the first light may be red light, the light of the second light may be green light, and the light of the third light may be blue light. However, examples of light of a color are not limited to the foregoing examples.

The first to third emission areas PXA-R, PXA-G and PXA-B may be repeatedly disposed with a certain or desired or given arrangement in the display area DA. A plurality of each of the first to third emission areas PXA-R, PXA-G and PXA-B may be disposed with a given arrangement. The first emission areas PXA-R may be aligned in the first direction DR1 to constitute or otherwise define a first column, the second emission areas PXA-G may be aligned in the first direction DR1 to constitute or otherwise define a second column, and the third emission areas PXA-B may be aligned in the first direction DR1 to constitute or otherwise define a third column. A plurality of each of the first column including the first emission areas PXA-R, the second column including the second emission areas PXA-G, and the third column including the third emission areas PXA-B may be provided and aligned in the second direction DR2.

The arrangement of the first to third emission areas PXA-R, PXA-G and PXA-B illustrated in FIG. 5 is provided as an example, and the arrangement of the emission areas is not limited thereto and may vary based on application and/or design of the electronic device EA (see FIG. 3). For example, the shapes, the surface areas, the arrangement and the like of the emission areas may be designed according to the emission efficiency of light depending on colors, and are not limited to example embodiments illustrated in FIG. 5.

The first to third emission areas PXA-R, PXA-G and PXA-B may have different shapes on a plane. For example, each of the first to third emission areas PXA-R, PXA-G and PXA-B may have an oval shape as illustrated in FIG. 5. However, example embodiments of the inventive concepts are not limited thereto, and each of the first to third emission areas PXA-R, PXA-G and PXA-B may have a polygonal shape, a circular shape, or an irregular shape.

The first to third emission areas PXA-R, PXA-G and PXA-B may have the same shape on a plane. However, example embodiments of the inventive concepts are not limited thereto, and at least some of the first to third emission areas PXA-R, PXA-G and PXA-B may have different shapes. The first to third emission areas PXA-R, PXA-G and PXA-B may have the same surface area. However, example embodiments of the inventive concepts are not limited thereto, and at least one or more of the first to third emission areas PXA-R, PXA-G and PXA-B may have different surface areas on a plane. The surface areas of the first to third emission areas PXA-R, PXA-G and PXA-B may be based on the colors of the emitted light.

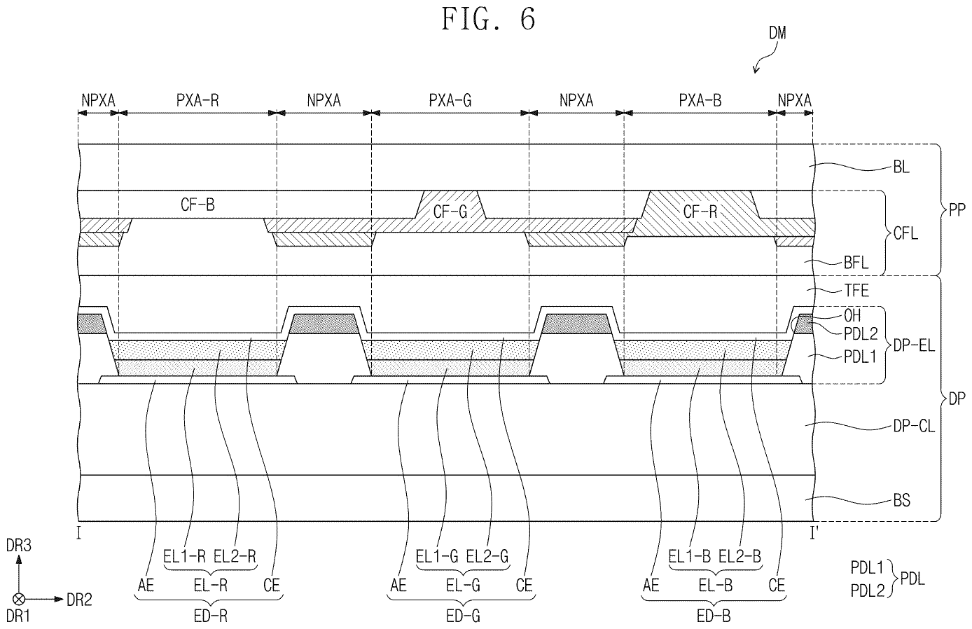

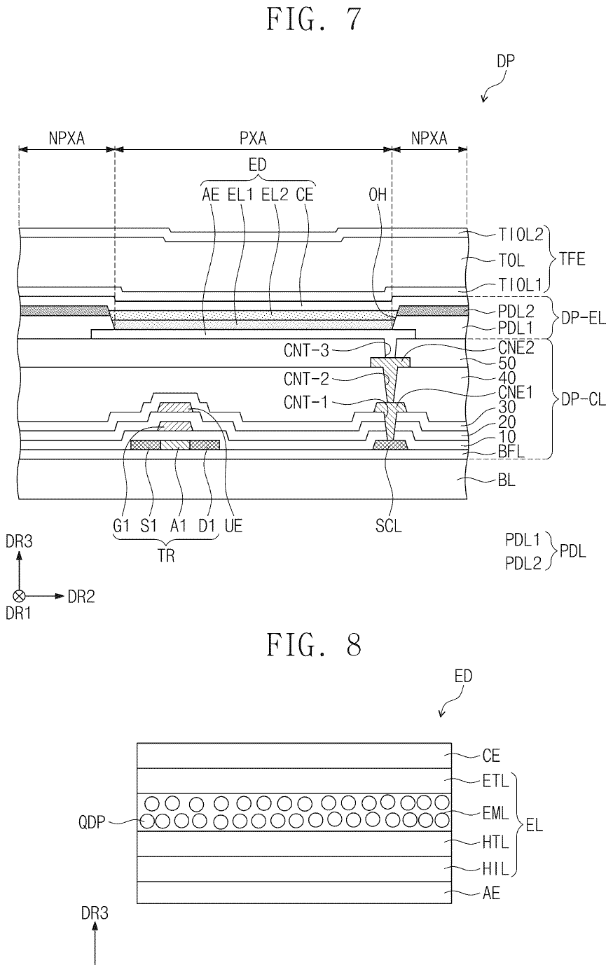

FIG. 6 is a cross-sectional view of a display device according to some example embodiments of the inventive concepts. FIG. 7 is a cross-sectional view of a portion of a display panel according to some example embodiments of the inventive concepts. FIG. 8 is a cross-sectional view of a light emitting element according to some example embodiments of the inventive concepts. FIG. 6 is a cross-sectional view corresponding to line I-I′ in FIG. 5. As an example, FIG. 7 illustrates a light emitting element ED, a transistor TR, and the like which are included in any one pixel included in a display panel DP according to some example embodiments. As an example, FIG. 8 illustrates a stack structure of the light emitting element ED in relative detail. As illustrated in each of FIGS. 7 and 8, the light emitting element ED may indicate one of light emitting elements ED-R, ED-G and ED-B illustrated in FIG. 6, and a functional layer EL may indicate one of functional layers EL-R, EL-G and EL-B illustrated in FIG. 6.

Referring to FIGS. 6 and 7, a display device DM according to some example embodiments may include the display panel DP. The display panel DP may be a component that substantially generates image data. The display panel DP according to some example embodiments may be a component that is included in the electronic device EA according to some example embodiments (see FIG. 3) and displays an image. The display panel DP according to some example embodiments may be an emissive display panel. In some example embodiments, the display panel DP may include an inorganic luminous body such as quantum dot.

The display panel DP may include a base layer BS, a circuit layer DP-CL, a display layer DP-EL, and an encapsulation layer TFE which are stacked in sequence in a third directional axis DR3 direction.

In the display panel DP, the base layer DP may be a member that provides a base surface on which the display layer DP-EL and the circuit layer DP-CL are disposed. The base layer BS may be a glass substrate, a metal substrate, a plastic substrate, or the like. However, example embodiments are not limited thereto, and the base layer BS may be an inorganic layer, an organic layer, or a composite material layer.

The circuit layer DP-CL includes at least one insulating layer and a circuit element. The circuit element includes a signal line, a driving circuit of a pixel, and the like. The circuit layer DP-CL may be formed by performing a process of forming an insulating layer, a semiconductor layer, and a conductive layer through coating, deposition, or the like, and a process of patterning the insulating layer, the semiconductor layer, and the conductive layer through photolithography.

A buffer layer BFL may include at least one stacked inorganic layer. A semiconductor pattern is disposed on the buffer layer BFL. The buffer layer BFL improves bonding force between the base layer BS and the semiconductor pattern.

The semiconductor pattern may include polysilicon. However, example embodiments of the inventive concepts are not limited thereto, and the semiconductor pattern may include amorphous silicon or a metal oxide. FIG. 7 illustrates a portion of the semiconductor pattern, and the semiconductor pattern may be further disposed in another area of the pixel on a plane. The semiconductor pattern may be arranged over pixels according to a specific or given design.

The semiconductor pattern has different electrical properties according to whether the semiconductor pattern is doped or not. The semiconductor pattern may include a first region A1 having low doping concentration and conductivity, and second regions S1 and D1 each having relatively high doping concentration and conductivity. One second region S1 may be disposed on one side of the first region A1, and the other second region D1 may be disposed on the other side of the first region A1. The second regions S1 and D1 may be doped with n-type dopants or p-type dopants. A p-type transistor includes a doped region doped with the p-type dopant. The first region A1 may be a non-doped region or be doped at a lower concentration than each of the second regions S1 and D1.

Each of the second regions S1 and D1 operates as an electrode or a signal line. One second region S1 may correspond to a source of a transistor, and the other second region D1 may correspond to a drain of the transistor. FIG. 7 illustrates a portion of a connection signal line SCL formed from the semiconductor pattern. In some example embodiments, the connection signal line SCL may be connected to a drain of the transistor TR on a plane.

A first insulating layer 10 may be disposed on the buffer layer BFL. The first insulating layer 10 overlaps, in common, a plurality of pixels disposed in a display area DA and covers the semiconductor pattern. The first insulating layer 10 may be an inorganic layer and/or an organic layer and may have a single-layer structure or a multilayer structure. The first insulating layer 10 may include at least one of aluminum oxide, titanium oxide, silicon oxide, silicon oxynitride, zirconium oxide, or hafnium oxide. In addition to the first insulating layer IL1, an insulating layer of the circuit layer DP-CL may be an inorganic layer and/or an organic layer and may have a single-layer structure or a multilayer structure.

A gate G1 is disposed on the first insulating layer 10. The gate G1 may be a portion of a metal pattern. The gate G1 overlaps the first region A1. The gate G1 may function or operate or may otherwise be configured as a mask in the process of doping the semiconductor pattern.

A second insulating layer 20 may be disposed on the first insulating layer 10 and cover the gate GT. The second insulating layer 20 overlaps the pixels in common. An upper electrode UE may be disposed on the second insulating layer 20. The upper electrode UE may overlap the gate G1. The upper electrode UE may include a metal layer having a multilayer structure. In some example embodiments of the inventive concepts, the upper electrode UE may be omitted.

A third insulating layer 30 may be disposed on the second insulating layer 20 and cover the upper electrode UE. A first connection electrode CNE1 may be disposed on the third insulating layer 30. The first connection electrode CNE1 may be connected to the connection signal line SCL through a contact hole CNT-1 passing through the first to third insulating layers 10 to 30.

A fourth insulating layer 40 may be disposed on the third insulating layer 30, and an organic layer 50 may be disposed on the fourth insulating layer 40. A second connection electrode CNE2 may be disposed on the organic layer 50. The second connection electrode CNE2 may be connected to the first connection electrode CNE1 through a contact hole CNT-2 passing through the fourth insulating layer 40. The organic layer 50 may be disposed on the fourth insulating layer 40 and cover the second connection electrode CNE2.

The light emitting element ED may be disposed on the organic layer 50. The light emitting element ED includes a first electrode AE, the functional layer EL, and a second electrode CE which are stacked in sequence. The first electrode used herein may be referred to as “first anode” or “second anode”, and the second electrode used herein may be referred to as “first cathode” or “second cathode”.

The first electrode AE may be disposed on the organic layer 50. The first electrode AE is connected to the second connection electrode CNE2 through a contact hole CNT-3 passing through the organic layer 50.

The display layer DP-EL may include the light emitting elements ED-R, ED-G and ED-B. A plurality of emission areas PXA-R, PXA-G and PXA-B may be respectively areas through which light generated from the light emitting elements ED-R, ED-G and ED-B is emitted. The light emitting elements ED-R, ED-G and ED-B may emit light having different wavelengths. For example, in some example embodiments, a first light emitting element ED-R may correspond to a red light emitting element that emits red light, a second light emitting element ED-G may correspond to a green light emitting element that emits green light, and a third light emitting element ED-B may correspond to a blue light emitting element that emits blue light.

A pixel defining film PDL may separate the first to third light emitting elements ED-R, ED-G and ED-B. Each of non-emission areas NPXA may be an area disposed between neighboring emission areas of the first to third emission areas PXA-R, PXA-G and PXA-B, and an area corresponding to the pixel defining film PDL. The functional layers EL-R, EL-G and EL-B of the first to third light emitting elements ED-R, ED-G and ED-B may be separated as disposed in pixel opening portions OH defined in the pixel defining film PDL.

The pixel defining film PDL may include a polymer resin. For example, the pixel defining film PDL may include a polyacrylate-based resin or a polyimide-based resin. In addition, the pixel defining film PDL may further include an inorganic material in addition to the polymer resin. The pixel defining film PDL may include a light absorbing material, or include a black pigment or a black dye. The pixel defining film PDL including the black pigment or the black dye may achieve a black pixel defining film. A carbon black or the like may be used as the black pigment or the black dye in the formation of the pixel defining film PDL, but some example embodiments are not limited thereto.

In addition, the pixel defining film PDL may include an inorganic material. For example, the pixel defining film PDL may include the inorganic material such as silicon nitride (SiNₓ), silicon oxide (SiOₓ), or silicon oxynitride (SiOₓN_{y}).

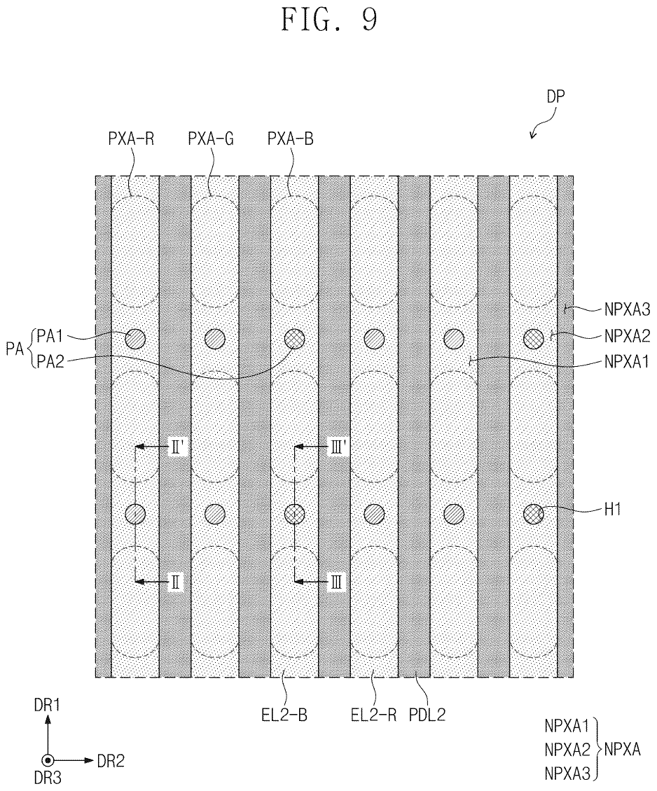

The pixel defining film PDL may include a first layer PDL1 and a second layer PDL2 disposed on the first layer PDL1. The second layer PDL2 may have a higher liquid-repellency than the first layer PDL1. A contact angle of the second layer PDL2 to one material may be larger than a contact angle of the first layer PDL1 to the one material. For example, a contact angle of the second layer PDL2 to methyl ethyl benzene may be about 65 degrees to about 80 degrees, and a contact angle of the first layer PDL1 to methyl ethyl benzene may be about 50 degrees to about 60 degrees. As described later with reference to FIG. 9, the first layer PDL1 may be arranged to correspond to an entire surface of the non-emission area NPXA, and the second layer PDL2 may be patterned to overlap only a portion of the non-emission area NPXA.

The encapsulation layer TFE may be directly disposed on the display layer DP-EL. The encapsulation layer TFE may cover the light emitting elements ED-R, ED-G and ED-B. The encapsulation layer TFE may seal the display layer DP-EL. The encapsulation layer TFE may be a thin-film encapsulation layer. The encapsulation layer TFE may be one in which a plurality of layers are stacked.

The encapsulation layer TFE according to some example embodiments may include at least one inorganic film (hereinafter referred to as an inorganic encapsulation film) and at least one organic film (hereinafter referred to as an organic encapsulation film). In some example embodiments, the encapsulation layer TFE may include a first inorganic encapsulation film TIOL1, an organic encapsulation film TOL, and a second inorganic encapsulation film TIOL2 which are stacked in sequence on the display layer DP-EL.

The inorganic encapsulation films TIOL1 and TIOL2 protect the display layer DP-EL from moisture/oxygen, and the organic encapsulation film TOL protects the display layer DP-EL from foreign matter (or debris) such as dust particles. The inorganic encapsulation films TIOL1 and TIOL2 may include silicon nitride, silicon oxynitride, silicon oxide, titanium oxide, aluminum oxide, or the like, and are not limited thereto.

The organic encapsulation layer TOL may include an acrylic compound, an epoxy-based compound, or the like.

The display device DM according to some example embodiments may include an optical member PP. The optical member PP may be disposed on the display panel DP. The optical member PP may be disposed on the display panel DP and control reflected light from the display panel DP due to external light. For example, the optical member PP may include a polarizing film including a retarder and/or a polarizer, a plurality of reflective layers that cause reflected light to destructively interfere with each other, or color filters arranged to correspond to arrangement and emissive colors of the pixels in the display panel DP. Alternatively, the optical member PP may be omitted in some example embodiments.

The optical member PP may include a base substrate BL and a color filter layer CFL.

The base substrate BL may provide a base surface on which the color filter layer CFL or the like is disposed. The base substrate BL may be a glass substrate, a metal substrate, a plastic substrate, or the like. However, example embodiments are not limited thereto, and the base substrate BL may be an inorganic layer, an organic layer, or a composite material layer.

The color filter layer CFL may include first to third color filters CF-R, CF-G and CF-B. The first to third color filters CF-R, CF-G and CF-B may be arranged to correspond to the first to third light emitting elements ED-R, ED-G and ED-B, respectively. For example, the first color filter CF-R may be a red filter, the second color filter CF-G may be a green filter, and the third color filter CF-B may be a blue filter. The first to third color filters CF-R, CF-G and CF-B may be arranged to correspond to the first to third emission areas PXA-R, PXA-G and PXA-B, respectively.

In addition, the plurality of color filters CF-R, CF-G and CF-B which transmit different light may be arranged to overlap each other in an area corresponding to the non-emission area NPXA disposed between the emission areas PXA-R, PXA-G and PXA-B. The plurality of color filters CF-R, CF-G and CF-B may be arranged to overlap each other in the third direction DR3 that is a thickness direction, thereby defining a boundary between adjacent emission areas of the emission areas PXA-R, PXA-G and PXA-B. Accordingly, an effect of blocking external light may be increased to have a function that is the same as or similar in some respects as a black matrix. A superposed structure of the plurality of color filters CF-R, CF-G and CF-B may have a function to prevent (or reduced or limit) color mixing.

Each of the first to third color filters CF-R, CF-G and CF-B may include a polymer photosensitive resin and a pigment or a dye. The first color filter CF-R may include a red pigment or a red dye, the second color filter CF-G may include a green pigment or a green dye, and the third color filter CF-B may include a blue pigment or a blue dye. However, example embodiments are not limited thereto, and the third color filter CF-B may not include a pigment or a dye. The third color filter CF-B may include a polymer photosensitive resin but not include a pigment or dye. The third color filter CF-B may be transparent. The third color filter CF-B may include a transparent photosensitive resin.

The color filter layer CFL may further include the buffer layer BFL. For example, the buffer layer BFL may be a protective layer that protects the first to third color filters CF-R, CF-G and CF-B. The buffer layer BFL may be an inorganic material layer including at least one inorganic material among silicon nitride, silicon oxide, or silicon oxynitride. The buffer layer BFL may include a single layer or a plurality of layers.

Alternatively, the first color filter CF-R and the second color filter CF-G may be yellow filters. The first color filter CF-R and the second color filter CF-G may be provided as one body without being separated from each other.

The color filter layer CFL may further include a light blocking part. The light blocking part may be a black matrix. The light blocking part may include an organic light blocking material or an inorganic light blocking material each including a black pigment or a black dye. The light blocking part may prevent (or reduce or limit) light leakage and define a boundary between adjacent color filters of the color filters CF-R, CF-G and CF-B.

Alternatively, the optical member PP of the display device DM according to some example embodiments may not include the color filter layer CFL.

Referring to FIGS. 6 to 8, in the display panel DP according to some example embodiments, the first to third light emitting elements ED-R, ED-G and ED-B may include first electrodes AE, functional layers EL-R, EL-G and EL-B, and second electrodes CE, respectively. In addition, each of the light emitting elements ED-R, ED-G and ED-B may include a capping layer disposed on the second electrode CE.

The first electrode AE may be exposed in each of the pixel opening portions OH of the pixel defining film PDL. The first electrode AE has conductivity. The first electrode AE may include a metal material, a metal alloy, or a conductive compound. The first electrode AE may be an anode or a cathode. The first electrode AE may also be a pixel electrode. The first electrode AE may be a transmissive electrode, a semi-transmissive electrode, or a reflective electrode.

The second electrode CE may be disposed on the first electrode AE. The second electrode CE may be arranged opposite the first electrode AE with an emission layer EML-R, EML-G or EML-B therebetween. The second electrode CE may be a cathode or an anode. In some example embodiments, in a case in which the first electrode AE is an anode, the second electrode CE may be a cathode, and in a case in which the first electrode AE is a cathode, the second electrode CE may be an anode. The second electrode CE may be a common electrode. The second electrode CE may be a transmissive electrode, a semi-transmissive electrode, or a reflective electrode.

The first electrode AE may be divided to correspond to each of the emission areas PXA-R, PXA-G and PXA-B. The second electrode CE may be provided as a common layer to the entirety of the emission areas PXA-R, PXA-G and PXA-B.

The functional layers EL-R, EL-G and EL-B may be divided into first emission parts EL1-R, EL1-G and EL1-B (collectively, first emission part EL1) and second emission parts EL2-R, EL2-G and EL2-B (collectively, second emission part EL2) disposed on the respective first emission parts EL1-R, EL1-G and EL1-B. As used herein, a first emission part EL1 may refer to one group of some components of the functional layer EL, which correspond to only the emission areas PXA-R, PXA-G and PXA-B, and a second emission part EL2 may refer to one group of the other components of the functional layer EL, which correspond to the emission areas PXA-R, PXA-G and PXA-B and at least partially overlap the non-emission area NPXA. The second emission parts EL2 may be a group extending in the first direction DR1 and spaced apart from each other in the second direction DR2, as described later with reference to FIG. 9.

Referring to FIG. 8, the functional layer EL may include a hole injection layer HIL, a hole transport layer HTL, an emission layer EML, and an electron transport layer ETL which are stacked in sequence. For example, the first emission part EL1 may include the hole injection layer HIL, the hole transport layer HTL, and the emission layer EML, and the second emission part EL2 may include the electron transport layer ETL. In some example embodiments, the first emission part EL1 may include the hole injection layer HIL and the hole transport layer HTL, and the second emission part EL2 may include the emission layer HTL and the electron transport layer ETL.

The hole injection layer HIL and the hole transport layer HTL may each include a general hole transport material. At least one of a buffer layer, an emission auxiliary layer, or an electron blocking layer may be further included on the first electrode AE.

The hole injection layer HIL and the hole transport layer HTL may each include a phthalocyanine compound such as copper phthalocyanine, N1,N1′-([1,1′-biphenyl]-4,4′-diyl)bis(N1-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-Tris(N,N-diphenylamino)triphenylamine (TDATA), 4,4′,4″-tris[N(2-naphthyl)-N-phenylamino]-triphenylamine (2-TNATA), Poly(3,4-ethylenedioxythiophene)/Poly(4-styrenesulfonate) (PEDOT/PSS), Polyaniline/Dodecylbenzenesulfonic acid (PANI/DBSA), Polyaniline/Camphor sulfonicacid (PANI/CSA), Polyaniline/Poly(4-styrenesulfonate) (PANI/PSS), N,N′-di(naphthalene-1-yl)-N,N′-diphenyl-benzidine (NPB), triphenylamine-containing polyetherketone (TPAPEK), 4-Isopropyl-4′-methyldiphenyliodonium [Tetrakis(pentafluorophenyl)borate], dipyrazino[2,3-f: 2′,3′-h] quinoxaline-2,3,6,7,10,11-hexacarbonitrile (HATCN), or the like.

The hole injection layer HIL and the hole transport layer HTL may each include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl), mCP(1,3-Bis(N-carbazolyl)benzene (HMTPD), or the like.

In addition, the hole injection layer HIL and the hole transport layer HTL may each include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

The emission layers EML-R, EML-G and EML-B may include quantum dots. The emission layer EML according to some example embodiments may include a plurality of quantum dots QDP.

As used herein, the quantum dots QDP refer to crystals of a semiconductor compound. The quantum dots QDP may emit light having various emission wavelengths according to sizes of the crystals. The quantum dots QDP may also emit light having various emission wavelengths by adjusting ratios of elements in the semiconductor compound.

A core of the quantum dots QDP may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnST, and a mixture thereof. The Group II-VI semiconductor compound may further include a Group I metal and/or the Group IV element. A Group I-II-VI compound may be selected from CuSnS or CuZnS, and a Group II-IV-VI compound may be selected from ZnSnS or the like. A Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, a Group III-II-V compound may be selected from InZn or the like.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V compound may include a ternary compound selected from the group consisting of ZnSnP, ZnSnP₂, ZnSnAs₂, ZnGeP₂, ZnGeAs₂, CdSnP₂, and CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each of elements included in a multi-element compound such as binary compound, ternary compound, and quaternary compound, may be present in a particle at a uniform concentration or non-uniform concentration. For example, the representation of a chemical formula representing the quantum dots QDP indicates types of elements included in a quantum dot compound, and a ratio of the elements in the compound may be different.

Here, the binary compound, the ternary compound, or the quaternary compound may be present at a uniform concentration in a particle, or may be divided in partially different concentration distributions and present in the same particle. In addition, the quantum dot may have a core/shell structure in which one quantum dot surrounds another quantum dot. In the core/shell structure, the quantum dot may have a concentration gradient in which the concentration of an element present in the shell gradually decreases toward the core.

The shell of the quantum dot QDP may function as a protective layer for preventing a chemical change of the core so as to maintain semiconductor characteristics, and/or as a charging layer for imparting electrophoretic characteristics to the quantum dot QDP. The shell may have a single-layer structure or a multilayer structure. Examples of the shell of the quantum dot may include an oxide of a metal or a non-metal, a semiconductor compound, or a combination thereof.

For example, the oxide of metal or non-metal may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but example embodiments of the inventive concepts are not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but example embodiments of the inventive concepts are not limited thereto.

For example, when the quantum dot of the Group III-V compound has a core-shell structure, the quantum dot may include InP or InZnP as a core and include ZnSeS as a shell, or have a dual shell structure of ZnSe/ZnS. However, example embodiments are not limited thereto, and the quantum dot may have a combination of a core and a shell which are selected from the foregoing semiconductor compounds.

The quantum dot QDP may have a full width of half maximum (FWHM) of an emission wavelength spectrum of 45 nm (or about 45 nm) or less, 40 nm (or about 40 nm) or less, 30 nm (or about 30 nm) or less, and, in this range, color purity or color reproducibility may be improved. Moreover, light emitted through this quantum dot may be emitted in all directions, and thus a wide viewing angle may be improved.

In addition, the form of the quantum dot QDP includes a form generally used in the relevant field and is not particularly limited. For example, spherical, pyramidal, multi-armed, or cubic nanoparticles, or particles in the form of nanotubes, nanowires, nanofibers, or nanoplate, or the like, may be used.

In the quantum dots QDP, an energy band gap may be adjusted by adjusting the sizes of the quantum dots or adjusting the ratios of elements in the quantum dot compound, and thus light having various wavelength bands may be obtained from the emission layer EML including the quantum dots QDP. Thus, the quantum dots (having different sizes or having different ratios of elements in the quantum dot compound) as described above may be used to achieve a light emitting element that emits light having several wavelengths. For example, the sizes of the quantum dots or the ratios of elements in the quantum dot compound may be selectively adjusted so as to emit light of a red color, a green color and/or a blue color. In addition, the quantum dots QDP may be configured so as to emit light of a white color by combining light of various colors.

In some example embodiments, as the quantum dot QDP is relatively smaller in particle size, the quantum dot may emit light in a shorter-wavelength range. For example, in quantum dots having the same core, a particle size of the quantum dot QDP which emits green light may be smaller than a particle size of the quantum dot which emits red light. In addition, in the quantum dots QDP having the same core, a particle size of the quantum dot which emits blue light may be smaller than the particle size of the quantum dot which emits the green light. However, example embodiments are not limited thereto, and, even in the quantum dots having the same core, the particle sizes thereof may be adjusted according to a material constituting the shell, a shell thickness, and the like. In a case in which quantum dots QDP have different emissive colors such as blue, red, and green colors, the quantum dots QDP having different emissive colors may have different core materials.

The electron transport layer ETL may include an electron transport material. At least one of an electron injection layer, a buffer layer, an emission auxiliary layer, or an electron blocking layer may be further included on the emission layer EML.

The electron transport layer ETL may include a metal oxide. An electron transport region ETR may include at least one of types of metal oxides such as Li₂O, BaO, ZnO, ZnMgO, or MgO.

The electron transport layer ETL may further include the other electron transport materials. For example, the electron transport region ETR may include Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), berylliumbis(benzoquinolin-10-olate) (Bebq₂), 9,10-di(naphthalene-2-yl)anthracene (ADN), 1,3-Bis[3,5-di(pyridin-3-yl)phenyl]benzene (BmPyPhB), and a mixture thereof, or 8-hydroxyl-Lithium quinolate (Liq) or the like.

In addition to the foregoing material, the electron transport layer ETL may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen), but example embodiments are not limited thereto.

The light emitting element ED may further include a capping layer. The capping layer may be disposed on the second electrode CE. In a case in which the capping layer includes an inorganic material, the inorganic material may include an alkali metal compound such as LiF, an alkali earth metal compound such as MgF₂, SiON, SiNₓ, SiO_{y}, or the like. In a case in which the capping layer includes an organic material, the organic material may include α-NPD, NPB, TPD, m-MTDATA, Alq₃, CuPc, N4,N4,N4′, N4′-tetra (biphenyl-4-yl) biphenyl-4,4′-diamine (TPD15), 4,4′,4″-Tris (carbazol sol-9-yl) triphenylamine (TCTA), or the like, or include epoxy resin, or acrylate such as a methacrylate. However, example embodiments are not limited thereto.

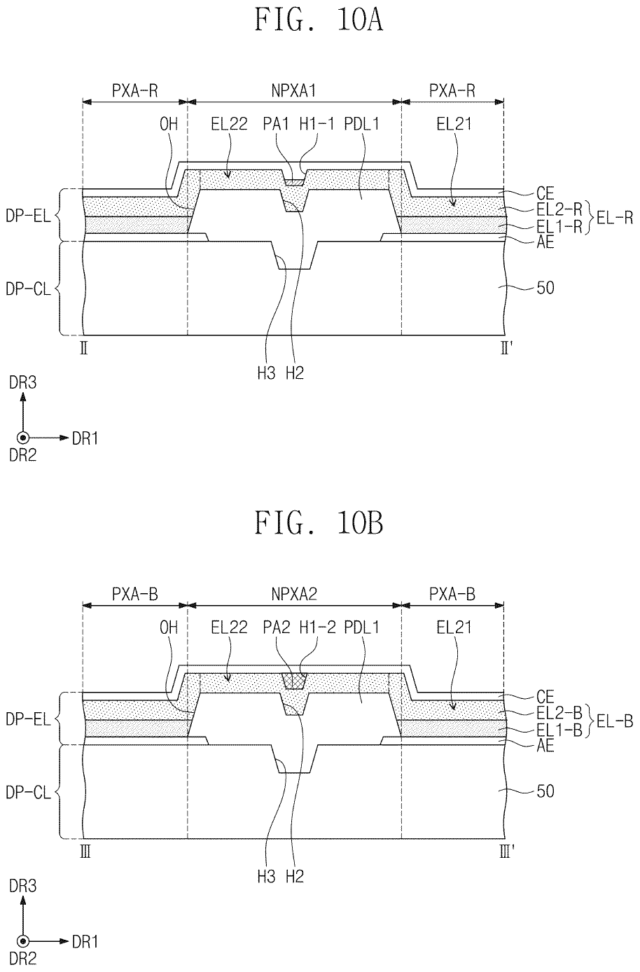

FIG. 9 is a plan view of a display panel according to some example embodiments of the inventive concepts. FIGS. 10A and 10B are each a cross-sectional view of a portion of a display panel according to some example embodiments of the inventive concepts. FIG. 9 illustrates a plan view corresponding to the display area DA illustrated in FIG. 6. For convenience of description, FIG. 9 illustrates one (single) component, disposed on a bottom surface of the second electrode CE (see FIG. 8), among components of a display panel DP according to an area. FIGS. 10A and 10B respectively illustrate cross-sectional views corresponding to lines II-II′ and III-III′ illustrated in FIG. 9. FIGS. 10A and 10B each illustrate a portion of the components of the display panel DP for sake of explanation. The display panel illustrated in FIGS. 10A and 10B may be same as or similar in some respects to the discussion above with reference to FIG. 8, and therefore may be best understood with reference thereto where like numerals indicate like elements not described again in detail.

Referring to FIGS. 9, 10A, and 10B, first grooves H1 are defined in top surfaces of functional layers EL-R and EL-B. The functional layers EL-R and EL-B may include first emission parts EL1-R and EL1-B and second emission parts EL2-R and EL2-B, and the first grooves H1 may be defined in top surfaces of the second emission parts EL2-R and EL2-B. The second emission parts EL2-R and EL2-B may include a first portion EL21 disposed in a pixel opening portion OH and a second portion EL22 disposed on a pixel defining film PDL1, and the first groove H1 may be defined in a top surface of the second portion EL22.

A non-emission area NPXA may include a first non-emission area NPXA1 and a second non-emission area NPXA2, and the first grooves H1 may include a plurality of (1-1)-th grooves H1-1 overlapping the first non-emission area NPXA1 and a plurality of (1-2)-th grooves H1-2 overlapping the second non-emission area NPXA2. The first non-emission area NPXA1 may refer to an area defined between a plurality of first emission areas PXA-R in the first direction DR1 or an area defined between a plurality of second emission areas PXA-G in the first direction DR1. As an example, FIGS. 10A and 10B illustrate the first non-emission area NPXA1 defined between the plurality of first emission areas PXA-R, but the description of the first non-emission area NPXA1 as below applies to the area defined between the plurality of second emission areas PXA-G. The second non-emission area NPXA2 may be an area defined between a plurality of third emission areas PXA-B in the first direction DR1.

The first grooves H1 and the emission areas PXA-R, PXA-G, and PXA-B may be alternated in the first direction DR1. The (1-1)-th grooves H1-1 and the first emission areas PXA-R may be alternated in the first direction DR1 to constitute a first column, the (1-1)-th grooves H1-1 and the second emission areas PXA-G may be alternated in the first direction DR1 to constitute a second column, and the (1-2)-th grooves H1-2 and the third emission areas PXA-B may be alternated in the first direction DR1 to constitute a third column. The first column, the second column, and the third column may be each provided in plurality to be alternated in the second direction DR2.

The pixel defining film PDL (see FIG. 6) may include a first layer PDL1 and a second layer PDL2 disposed on the first layer PDL1, and a second groove H2 corresponding to each of the first grooves H1 may be defined in a top surface of the first layer PDL1. The second layer PDL2 may be spaced apart from the first groove H1 and the second groove H2 on a plane. The first layer PDL1 may be arranged to correspond to an entire surface of the non-emission area NPXA, but the second layer PDL2 may be patterned to overlap a portion (e.g., only a portion) of the non-emission area NPXA. The second layer PDL2 may be arranged to correspond to a third non-emission area NPXA3. The first to third emission areas PXA-R, PXA-G and PXA-B may be aligned to be spaced apart from each other in the second direction DR2, and the third non-emission area NPXA3 may be an area defined between one area and another area of the first to third emission areas PXA-R, PXA-G and PXA-B in the second direction DR2.

As illustrated in FIG. 9, each of the second layer PDL2 and the second emission parts EL2-R and EL2-B may have a shape extending in the first direction DR1. The second layer PDL2 and the second emission parts EL2-R and EL2-B may be alternated in the second direction DR2.

A circuit layer DP-CL may include the plurality of insulating layers 10 to 40 (see FIG. 7) and an organic layer 50, and a third groove H3 corresponding to the first groove H1 and the second groove H2 may be defined in a top surface of the organic layer 50.

A pattern layer PA is disposed in the first groove H1. A material included in the pattern layer PA may be different from the materials included in the light emitting elements ED-R, ED-G and ED-B (see FIG. 6). The pattern layer PA may be or include an acid material. The acid material included in the pattern layer PA may include a polyacrylic acid or a citric acid. The acid material included in the pattern layer PA may include both the polyacrylic acid and the citric acid. The acid material included in the pattern layer PA may supply hydrogen ions to the second emission parts EL2-R and EL2-B of the functional layers EL-R and EL-B. The acid material included in the pattern layer PA may supply the hydrogen ions to the electron transport layer ETL (see FIG. 8) included in the second emission parts EL2-R and EL2-B. The pattern layer PA used herein may be referred to as a “recess pattern”.

The pattern layer PA may include a first pattern layer PA1 and a second pattern layer PA2. The first pattern layer PA1 may be disposed in the (1-1)-th groove H1-1 overlapping the first non-emission area NPXA1, and the second pattern layer PA2 may be disposed in the (1-2)-th groove H1-2 overlapping the second non-emission area NPXA2. A thickness of the first pattern layer PA1 may be different from a thickness of the second pattern layer PA2. The thickness of the second pattern layer PA2 may be larger than the thickness of the first pattern layer PA1. The thickness of the second pattern layer PA2 may be 2 times (or about 2 times) to 4.5 times (or about 4.5 times) the thickness of the first pattern layer PA1. Accordingly, a fixed or given amount of the hydrogen ions supplied to the second emission part EL2-R in contact with the first pattern layer PA1 may be relatively smaller than a fixed amount of the hydrogen ions supplied to the second emission part EL2-B in contact with the second pattern layer PA2. However, example embodiments are not limited thereto, and the amounts of the hydrogen ions supplied to the second emission parts EL2-R and EL2-B may be adjusted based on designing factors such as the type and the fixed amount of the acid material included in each of the first pattern layer PA1 and the second pattern layer PA2.

The second electrode CE may be disposed on the pattern layer PA. A thickness of the second electrode CE may be 200 Å (or about 200 Å) to 2000 Å (or about 2000 Å). For example, the thickness of the second electrode CE may be 500 Å (or about 500 Å) to 1000 Å (or about 1000 Å). As the second electrode CE has the thickness within the foregoing range, the hydrogen ions generated from the acid material of the pattern layer PA may be limited or prevented from being supplied to another component above the second electrode CE. Accordingly, oxidation of one component included in the display panel DP may be limited or prevented and reliability thereof may be improved.

A display panel according to some example embodiments of the inventive concepts may include a pattern layer on a top surface of a light emitting element, thereby improving the luminance efficiency. In the light emitting element according to some example embodiments, a defect may occur when an electron transport layer includes a metal oxide. However, the display panel according to some example embodiments of the inventive concepts may include the pattern layer disposed on a second emission part and including an acid material, thereby preventing or reducing or limiting the defect in the metal oxide in the electron transport layer. For example, hydrogen ions supplied from the acid material of the pattern layer may passivate the defect in ZnO or ZnMgO included in the electron transport layer, thereby improving electron injection of the electron transport layer. In addition, the pattern layer may be in contact with the second emission part but not in contact with a first emission part, and accordingly, the acid material may not be supplied to a hole transport layer and the like except for the electron transport layer, thereby preventing or reducing or limiting degradation in the hole transport layer and the like.

Moreover, in the display panel according to some example embodiments of the inventive concepts, the arrangement of the pattern layer may be different according to emission areas, thereby improving the element lifespan. Fixed amounts of the hydrogen ions used for light emitting elements included in first to third emission areas may be different. For example, an amount of the acid material used for a third light emitting element which emits blue light may be relatively larger than an amount of the acid material used for a first or second light emitting element which emits red light or green light. When the amount of the acid material used for the third light emitting element is supplied to the first or second light emitting element, the lifespan of the first or second light emitting element may be decreased. When the amount of the acid material used for the first or second light emitting element is supplied to the third light emitting element, the lifespan of the third light emitting element may be reduced (e.g., substantially reduced). In the display panel according to some example embodiments of the inventive concepts, the thickness of the pattern layer may be differently set according to the emissive colors of the emission areas, thereby improving optimum luminance efficiency for each of the red, green, and blue colors and obtaining improved lifespan characteristics from one display panel.

The display panel according to some example embodiments of the inventive concepts may include the pattern layer in the light emitting element, thereby improving the luminance efficiency and the element lifespan. Accordingly, an electronic device including the display panel according to some example embodiments of the inventive concepts may have improved display efficiency and reliability.

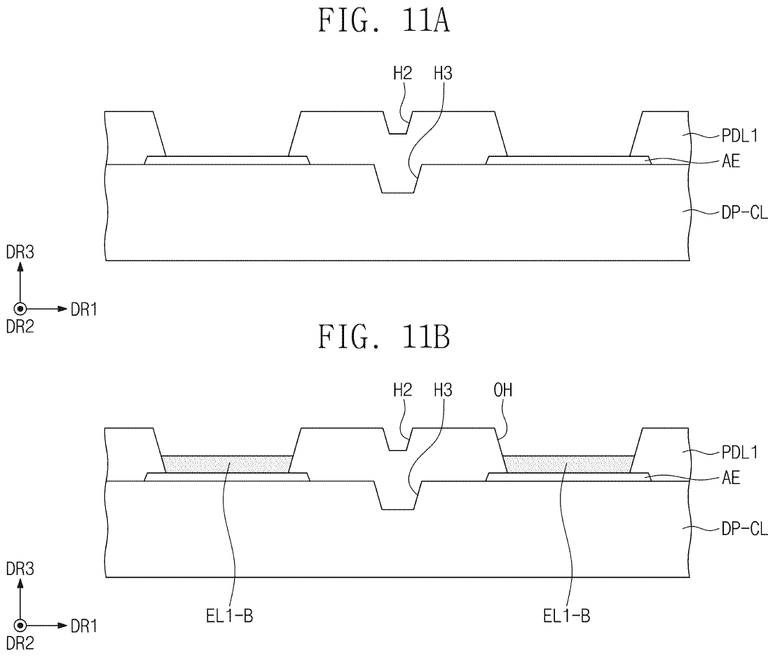

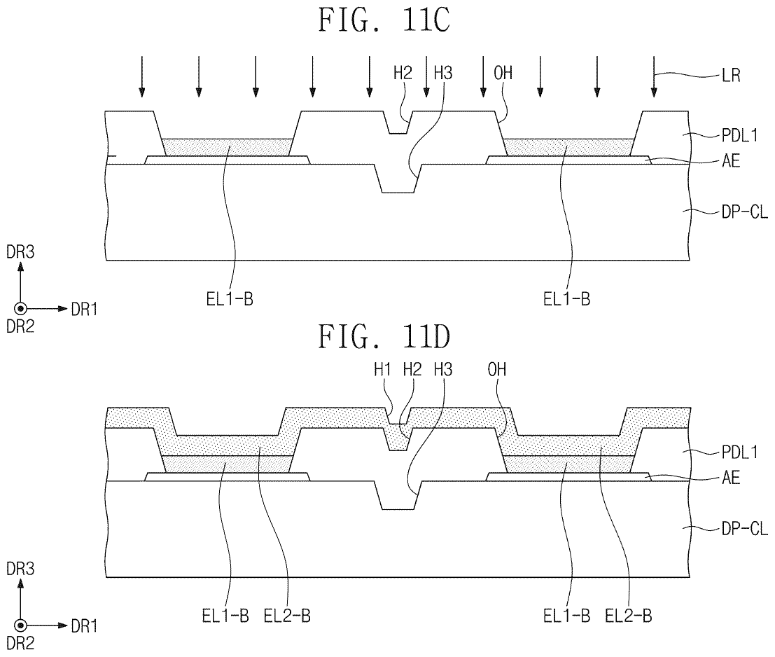

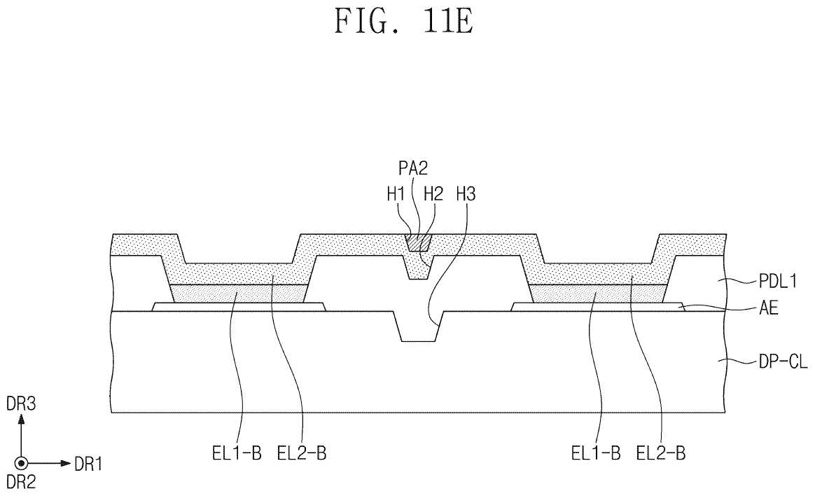

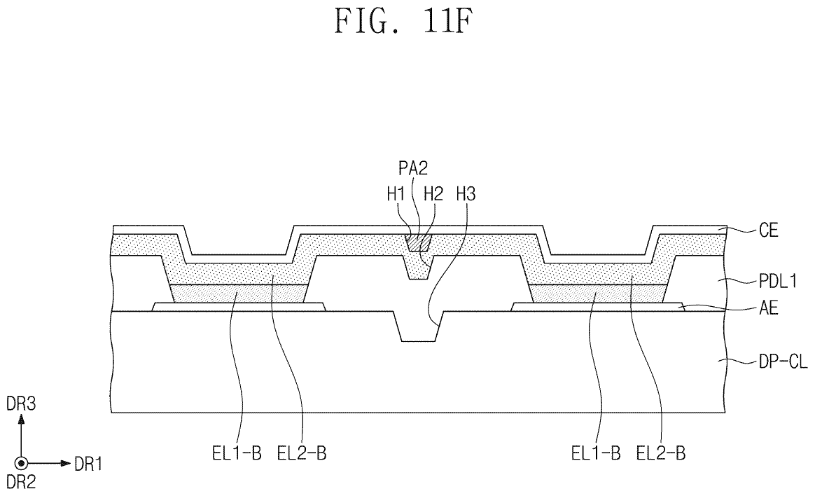

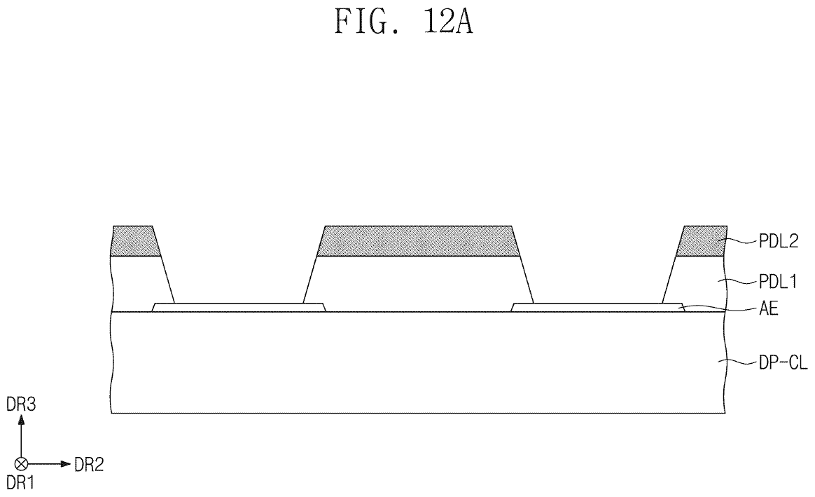

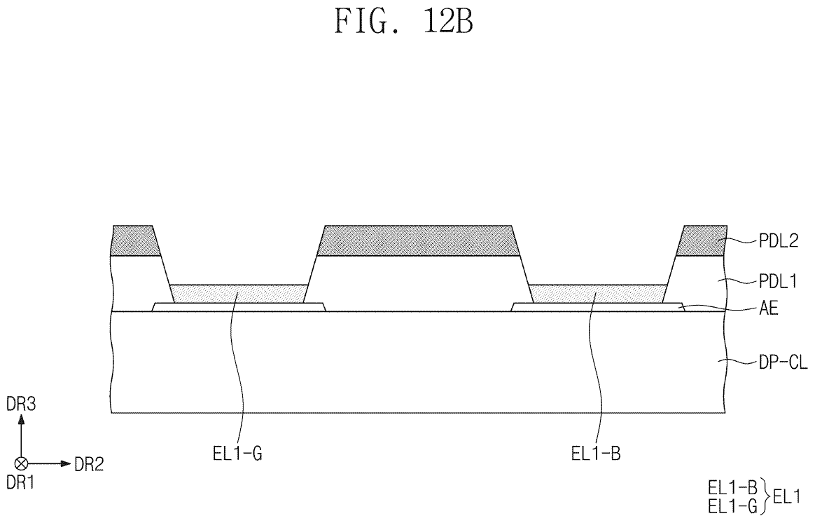

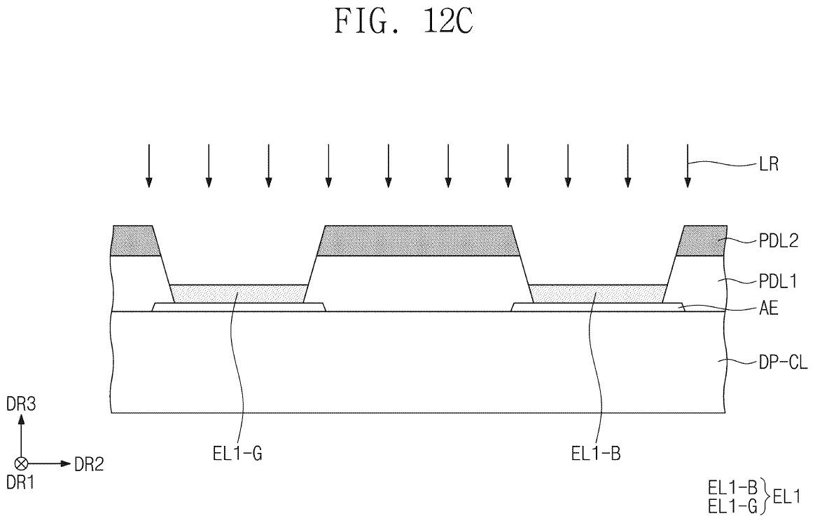

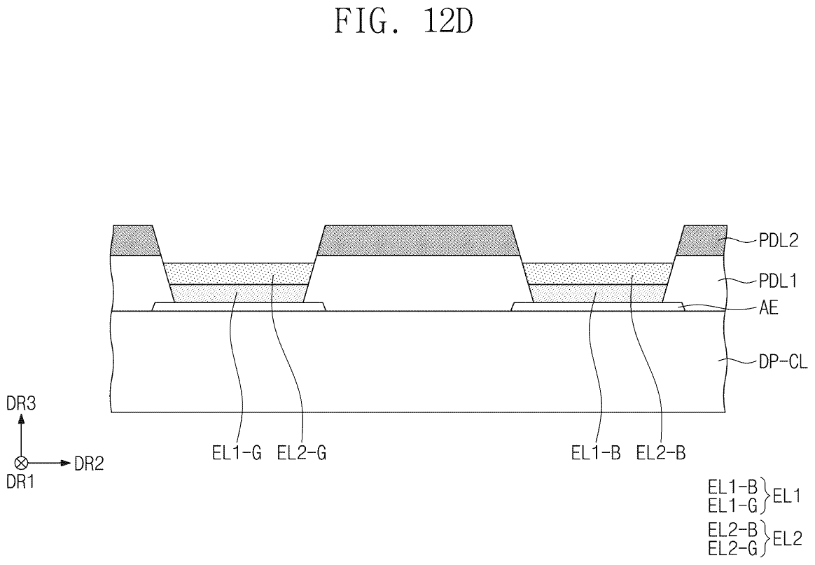

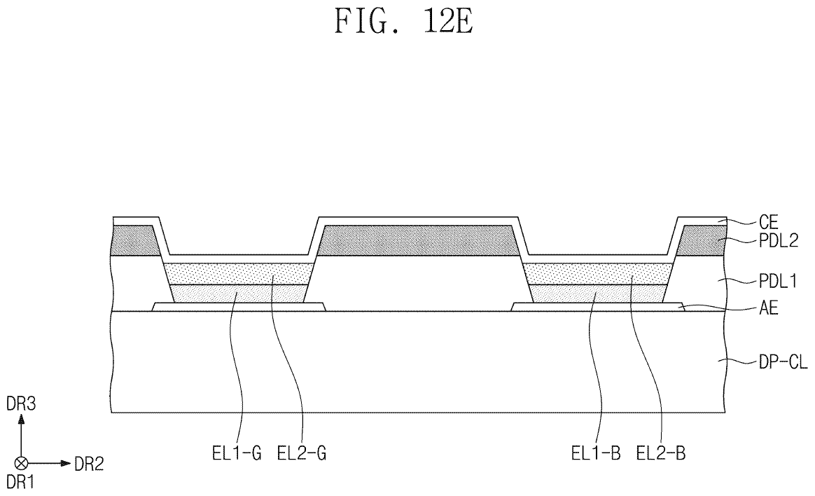

Hereinafter, a method for manufacturing a display panel according to some example embodiments is described with reference to FIGS. 11A to 11F and 12A to 12E. The method for manufacturing the display panel according to some example embodiments is described in terms of differences by avoiding the contents in common with the contents of the display panel according to some example embodiments described with reference to FIGS. 1 to 10B.

FIGS. 11A, 11B, 11C, 11D, 11E, and 11F illustrate example operations in a method for manufacturing a display panel according to some example embodiments. FIGS. 12A, 12B, 12C, 12D, 12E, and 12E illustrate example operations in a method for manufacturing a display panel according to some example embodiments. It is understood that additional operations can be provided before, during, and after the operations in FIGS. 11A, 11B, 11C, 11D, 11E, and 11F, and FIGS. 12A, 12B, 12C, 12D, 12E, and 12E, and some of the operations described below can be replaced or eliminated, for additional embodiments of the method. The order of the operations/processes may be interchangeable, or two or more operations can be performed simultaneously.

FIGS. 11A to 11F illustrate some components in the display panel, provided in any two emission areas adjacent to each other in the first direction DR1. As an example, FIGS. 11A to 11F illustrate the third emission areas PXA-B (see FIG. 9) adjacent to each other in the first direction DR1. FIGS. 12A to 12E illustrate some components in the display panel, provided in any two emission areas adjacent to each other in the second direction DR2. As an example, FIGS. 12A to 12E illustrate the second emission area PXA-G (see FIG. 9) and the third emission area PXA-B (see FIG. 9) adjacent to each other in the second direction DR2. FIGS. 11A and 12A correspond to cross-sectional views of processes in substantially the same operation when viewed in different directions DR1 and DR2, respectively. Likewise, each of FIGS. 11B and 12B, FIGS. 11C and 12C, FIGS. 11D and 12D, and FIGS. 11F and 12E may correspond to cross-sectional views of processes in substantially the same operation when viewed in the different directions DR1 and DR2.

Referring to FIGS. 11A and 12A, the method for manufacturing the display panel according to some example embodiments may include forming pixel defining films PDL1 and PDL2 on a circuit element layer DP-CL.

The pixel defining films PDL may include a first layer PDL1 and a second layer PDL2 disposed on the first layer PDL1. A second groove H2 may be defined in a top surface of the first layer PDL1. A third groove H3 may be defined in a top surface of the circuit element layer DP-CL.

A material included in the second layer PDL2 may have a higher liquid-repellency than a material included in the first layer PDL1. The second layer PDL2 may extend in the first direction DR1, and the second layer PDL2 provided in plurality may be arranged in the second direction DR2.

Referring to FIGS. 11B and 12B, the method for manufacturing the display panel according to some example embodiments may include forming first emission parts EL1-R and EL1-B in pixel opening portions OH. The forming of the first emission parts EL1-R and EL1-B may be performed through a printing process.

Referring to FIGS. 11C and 12C, the method for manufacturing the display panel according to some example embodiments may include providing light LR on the pixel defining films PDL1 and PDL2. The light LR may be provided for 0.1 second (or about 0.1 seconds) to 10 second (or about 10 seconds). The light LR may be ultraviolet light. The light LR may be provided on top surfaces of the pixel defining films PDL1 and PDL2, and accordingly, the liquid repellency of the top surfaces of the pixel defining films PDL1 and PDL2 may be reduced or become lower compared to the liquid repellency of the pixel defining films PDL1 and PDL2 prior to providing light LR. Accordingly, in some example embodiments, the second layer PDL2 (or only the second layer PDL2) may have (or exhibit) the liquid repellency, and the first layer PDL1 may relatively reduced liquid repellency or may effectively lose the liquid repellency.

Referring to FIGS. 11D and 12D, the method for manufacturing the display panel according to some example embodiments may include forming second emission parts EL2-G and EL2-B on the first emission parts EL1-G and EL1-B. The forming of the second emission parts EL2-G and EL2-B may be performed through a printing process.

The second emission part EL2 may be disposed on the top surface of the first layer PDL1 but not disposed on a top surface of the second layer PDL2. The second emission part EL2 may be disposed on the top surface of the first layer PDL1 which is not liquid-repellent, but may not be disposed on the top surface of the second layer PDL2 which is liquid-repellent. Accordingly, the second emission part EL2 may extend in the first direction DR1, and the plurality of second emission parts EL2 may be alternated with the plurality of second layers PDL2 in the second direction DR2.

A top surface of the second emission part EL2 disposed on the top surface of the first layer PDL1 may include a first groove H1 corresponding to the second groove H2 and the third groove H3. For example, as illustrated, the first groove H1 may be formed vertically aligning with the second groove H2 and the third groove H3.

Referring to FIG. 11E, the method for manufacturing the display panel according to some example embodiments may include disposing a pattern layer PA in the first groove H1 defined in the top surface of the second emission part EL2. As an example, FIG. 11E illustrates the pattern layer PA disposed between the third emission areas PXA-B (see FIG. 9). As described above with reference to FIG. 10B, a pattern layer PA disposed between first or second emission areas PXA-R or PXA-G may have a relatively smaller thickness than the pattern layer PA disposed between the third emission areas PXA-B (see FIG. 9).

Referring to FIGS. 11F and 12E, the method for manufacturing the display panel according to some example embodiments may include disposing a second electrode CE disposed on the pattern layer PA and the second emission part EL2. The second electrode CE may have a sufficiently large thickness such that an acid material included in the pattern layer PA may affect only the second emission part EL2 without being diffused to other adjacent components in the third direction DR3.

The display panel according to some example embodiments and the electronic device including the display panel may include the pattern layer disposed in the light emitting element, thereby exhibiting the improved luminance efficiency and longer lifespan.

In the display panel according to some example the embodiment and the electronic device including the display panel, the thickness of the pattern layer may be different according to the emission areas, thereby exhibiting improved luminance efficiency and lifespan characteristics.

In the above, description has been made with reference to embodiments of the inventive concepts, but those skilled or of ordinary skill in the art may understand that various modifications and changes may be made to the inventive concepts insofar as such modifications and changes do not depart from the spirit and technical scope of the inventive concepts set forth in the claims to be described later.

Therefore, the technical scope of the inventive concepts is not to be limited to the contents stated in the detailed description of the specification, but should be determined by the claims.

What is claimed is:

1. A display panel comprising:
a base layer comprising a plurality of emission areas and a non-emission area, the non-emission area surrounding the plurality of emission areas;
a circuit layer on the base layer; and
a display layer on the circuit layer and comprising a plurality of light emitting elements corresponding to the plurality of emission areas,
wherein each of the plurality of light emitting elements comprises,
a first electrode;
a second electrode on the first electrode;
a functional layer between the first electrode and the second electrode and having a top surface at least partially defining a first groove, the first groove at least partially overlapping the non-emission area; and
a pattern layer in the first groove,
wherein the pattern layer comprises an acid material.

2. The display panel of claim 1, wherein a material comprised in each of the plurality of light emitting elements is different from a material comprised in the pattern layer.

3. The display panel of claim 1, wherein the acid material comprises a polyacrylic acid or a citric acid.

4. The display panel of claim 1, wherein the functional layer comprises a first emission part on the first electrode, and a second emission part on the first emission part,
wherein the second emission part at least partially defines the first groove.

5. The display panel of claim 4, wherein the first emission part comprises a hole transport layer and an emission layer on the hole transport layer, and
the second emission part comprises an electron transport layer on the emission layer,
wherein the pattern layer is configured such that hydrogen ions from the acid material are provided to the electron transport layer.

6. The display panel of claim 4, wherein the first emission part comprises a hole transport layer, and
the second emission part comprises an emission layer on the hole transport layer, and an electron transport layer on the emission layer,
wherein the pattern layer is configured such that hydrogen ions from the acid material are provided to the electron transport layer.

7. The display panel of claim 4, wherein the display layer further comprises a pixel defining film that exposes at least a portion of a top surface of the first electrode through a pixel opening portion defined in the pixel defining film,
wherein the first emission part is in the pixel opening portion,
wherein the second emission part comprises a first portion in the pixel opening portion, and a second portion on the pixel defining film, the second portion having a top surface that defines the first groove.

8. The display panel of claim 7, wherein the pixel defining film comprises a first layer on the circuit layer, and a second layer on a top surface of the first layer, and
wherein the top surface of the first layer defines a second groove, the second groove corresponding to the first groove.

9. The display panel of claim 8, wherein the second layer is spaced apart from the first groove and the second groove on a plane.

10. The display panel of claim 8, wherein the second layer extends in a first direction.

11. The display panel of claim 8, wherein the second layer includes a material having a higher liquid-repellency than a material comprised in the first layer.

12. The display panel of claim 8, wherein the circuit layer comprises a plurality of insulating layers and an organic layer on the plurality of insulating layers,
wherein a top surface of the organic layer defines a third groove corresponding to the second groove.

13. The display panel of claim 1, wherein the plurality of emission areas comprise:
a plurality of first emission areas, each of which are configured to emit a first light and are aligned in a first direction; and
a plurality of second emission areas, each of which are configured to emit a second light and are aligned in the first direction.

14. The display panel of claim 13, wherein the first light is a red light or a green light, and the second light is a blue light.

15. The display panel of claim 13, wherein the non-emission area comprises a first non-emission area between the plurality of first emission areas, and a second non-emission area between the plurality of second emission areas.

16. The display panel of claim 15, wherein the first groove comprises a plurality of (1-1)-th grooves at least partially overlapping the first non-emission area, and a plurality of (1-2)-th grooves at least partially overlapping the second non-emission area,
wherein the plurality of (1-1)-th grooves and the plurality of first emission areas are alternated in the first direction, and
wherein the plurality of (1-2)-th grooves and the plurality of second emission areas are alternated in the first direction.

17. The display panel of claim 16, wherein the pattern layer comprises a first pattern layer in the plurality of (1-1)-th grooves, and a second pattern layer in the plurality of (1-2)-th grooves,
wherein a thickness of the first pattern layer is different from a thickness of the second pattern layer.

18. A display panel comprising:
a base layer comprising a plurality of first emission areas, each of which are configured to emit a first light, a plurality of second emission areas, each of which are configured to emit a second light different from the first light, a first non-emission area between the plurality of first emission areas, and a second non-emission area between the plurality of second emission areas;
a circuit layer on the base layer; and
a display layer on the circuit layer and comprising a plurality of first light emitting elements corresponding to the plurality of first emission areas, and a plurality of second light emitting elements corresponding to the plurality of second emission areas,
wherein each of the plurality of first light emitting elements comprises a first anode, a first cathode on the first anode, and a first functional layer between the first anode and the first cathode,
wherein each of the plurality of second light emitting elements comprises a second anode, a second cathode on the second anode, and a second functional layer between the second anode and the second cathode,
wherein a top surface of the first functional layer defines a first recess pattern that at least partially overlaps the first non-emission area, and
wherein a top surface of the second functional layer defines a second recess pattern that at least partially overlaps the second non-emission area and has a different thickness than the first recess pattern.

19. An electronic device comprising:
a display device configured to provide an image and comprising a display panel; and
a power module configured to supply power to the display device,
wherein the display panel comprises,
a base layer comprising a plurality of emission areas and a non-emission area surrounding the plurality of emission areas;
a circuit layer on the base layer; and
a display layer on the circuit layer and comprising a plurality of light emitting elements corresponding to the plurality of emission areas,
wherein each of the plurality of light emitting elements comprises,
a first electrode;
a second electrode on the first electrode;
a functional layer between the first electrode and the second electrode and having a top surface that defines a first groove, the first groove at least partially overlapping the non-emission area; and
a pattern layer in the first groove,
wherein the pattern layer comprises an acid material.

20. The electronic device of claim 19, further comprising a processor and a memory.
